(19) United States
(12) Patent Application Publication
(10) Pub. No.: US 2006/0175694 A1
(43) Pub. Date: Aug. 10, 2006

(54) Stacked structure of integrated circuits and method for manufacturing the same

(76) Inventors: Chung Hsien Hsin, Hsinchu Hsien (TW); Jayvee Huang, Hsinchu Hsien (TW)

Correspondence Address: PRO-TECHTOR INTERNATIONAL, 20775 Norada Court, Saratoga, CA, 95070-3018, US

(21) Appl. No.: 11/052,961

(22) Filed: Feb. 7, 2005

(51) Int. Cl. H01L 23/02

(52) U.S. Cl. 257/686

(57) ABSTRACT

A stacked structure of integrated circuits includes a substrate, a frame layer, an upper integrated circuit, a plurality of first wires, a plurality of spacer elements, a lower integrated circuit, a plurality of second wires, and a compound. The substrate has a first surface and a second surface on which a plurality of first electrodes are formed. The frame layer has an upper surface on which a plurality of second electrodes and third electrodes are formed and a lower surface, the lower surface of the frame layer is adhered to the first surface of the substrate. The lower integrated circuit is adhered onto the first surface of the substrate, a plurality of bonding pads are formed on the lower integrated circuit. The plurality of first wires are electrically connected the second electrodes of the frame layer to the bonding pads of the lower integrated circuit. The plural spacer elements are arranged on the lower integrated circuit. The upper integrated is located on the lower integrated circuit and adhered to the plurality of space elements, the plurality of bonding pads being formed on the upper integrated circuit. The plurality of second wires are electrically connected the third electrodes of the frame layer to the bonding pads of the upper integrated circuit. The compound resin is encapsulated the upper integrated circuit and the lower integrated circuit.

### BACKGROUND OF THE INVENTION

1. Field of the Invention

The invention relates to a structure of stacked integrated circuits, in particular, to a structure of stacked integrated circuits in which integrated circuits can be effectively stacked so as to facilitate the manufacturing processes.

2. Description of the Related Art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

To meet the demands of manufacturing small, thin, and light products, a lot of integrated circuits can be stacked. However, when stacking a lot of integrated circuits, the upper integrated circuit will contact and press the wirings of the lower integrated circuit. In this case, the signal transmission to or from the lower integrated circuit is easily influenced.

Referring to FIG. 1, a structure of stacked integrated circuits includes a substrate 10, a lower integrated circuit 12, an upper integrated circuit 14, a plurality of wirings 16, and an isolation layer 18. The lower integrated circuit 12 is located on the substrate 10. The isolation layer 18 is located on the lower integrated circuit 12. The upper integrated circuit 14 is stacked on the isolation layer 18. That is, the upper integrated circuit 14 is stacked above the lower integrated circuit 12 with the isolation layer 18 interposed between the integrated circuits 12 and 14. Thus, a proper gap 20 is formed between the lower integrated circuit 12 and the upper integrated circuit 14. According to this structure, the plurality of wirings 16 can be electrically connected to the edge of the lower integrated circuit 12. Furthermore, the plurality of wirings 16 connecting the substrate 10 to the lower integrated circuit 12 are free from being pressed when stacking the upper integrated circuit 14 above the lower integrated circuit 12.

However, the above-mentioned structure has the disadvantages to be described hereinbelow. During the manufacturing processes, the isolation layer 18 has to be manufactured in advance, and then, it is adhered to the lower integrated circuit 12. Thereafter, the upper integrated circuit 14 has to be adhered on the isolation layer 18. As a result, the manufacturing processes are complicated, and the manufacturing costs are high.

To solve the above-mentioned problems, it is necessary for the invention to provide a structure of stacked integrated circuits in order to improve the stacking processes of the integrated circuits, facilitate the manufacturing processes, and lower down the manufacturing costs.

### SUMMARY OF THE INVENTION

It is therefore an object of the invention to provide a structure of stacked integrated circuits in order to effectively stack the integrated circuits and increase the manufacturing speed.

According to one aspect of the invention, a stacked structure of integrated circuits includes a substrate, a frame layer, an upper integrated circuit, a plurality of first wires, a plurality of spacer elements, a lower integrated circuit, a plurality of second wires, and a compound. The substrate has a first surface and a second surface on which a plurality of first electrodes are formed. The frame layer has an upper surface on which a plurality of second electrodes and third electrodes are formed and a lower surface, the lower surface of the frame layer is adhered to the first surface of the substrate. The lower integrated circuit is adhered onto the first surface of the substrate, a plurality of bonding pads are formed on the lower integrated circuit. The plurality of first wires are electrically connected the second electrodes of the frame layer to the bonding pads of the lower integrated circuit. The plural spacer elements are arranged on the lower integrated circuit. The upper integrated is located on the lower integrated circuit and adhered to the plurality of space elements, the plurality of bonding pads being formed on the upper integrated circuit. The plurality of second wires are electrically connected the third electrodes of the frame layer to the bonding pads of the upper integrated circuit. The compound resin is encapsulated the upper integrated circuit and the lower integrated circuit.

### BRIEF DESCRIPTION OF THE DRAWINGS

FIG. 1 is a cross-sectional view showing a conventional stacked structure of integrated circuits.

FIG. 2 is a cross-sectional view showing a stacked structure of integrated circuits of the present invention.

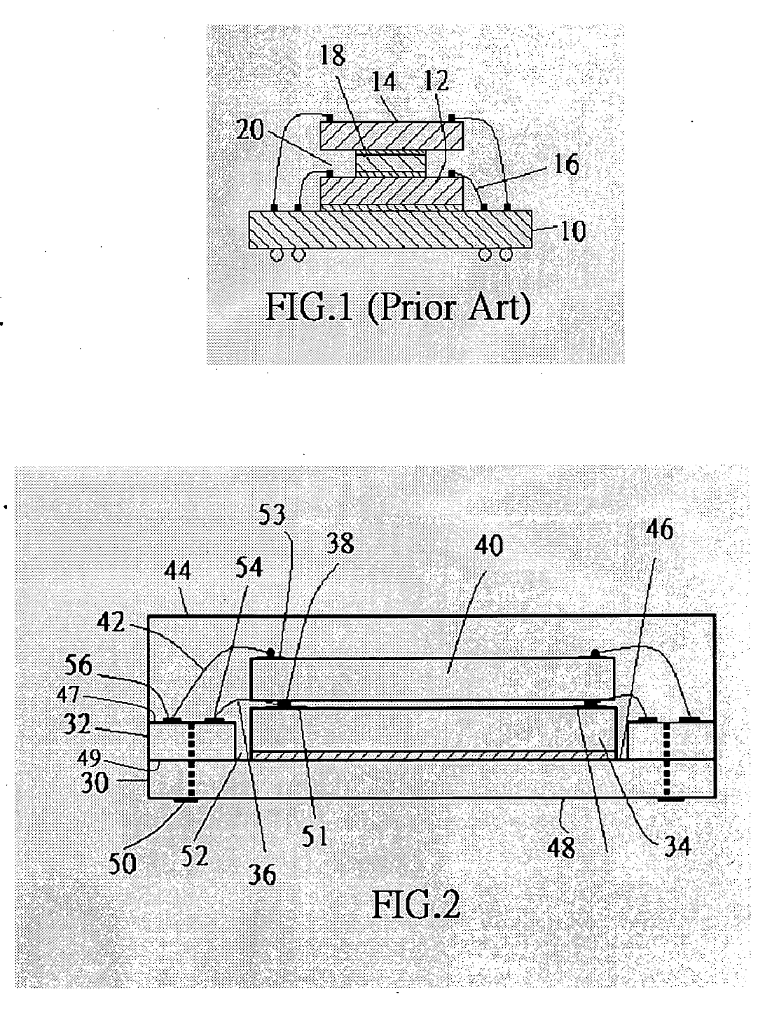

### DETAIL DESCRIPTION OF THE INVENTION

The embodiments of the invention will be described with reference to the accompanying drawings.

Referring to FIG. 2, the stacked structure of integrated circuits in accordance with an embodiment of the invention includes a substrate 30, a frame layer 32, a lower integrated circuit 34, a plurality of first wires36, a plurality of spacer elements 40, a plurality of second wires 42, and a compound resin 44.

The substrate 30 has a first surface 46 and a second surface 48 opposite to the first surface 46. The second surface 48 is formed with a plurality of first electrodes 50.

The frame layer32 has an upper surface 47 on which a plurality of second electrodes 54 and third electrodes 56 are formed and a lower surface 49 opposite to the upper surface 47. The lower surface 49 of the frame layer 32 is adhered to the first surface 46 of the substrate 30 so as to define a cavity 52 by the substrate 30 and the frame layer 32.

The lower integrated circuit 34 is adhered onto the first surface 46 of the substrate 30 and within the cavity 52, a plurality of bonding pads 51 are formed on the lower integrated circuit 34.

The plural of first wires 36 are electrically connected the second electrodes 54 of the frame layer 32 to the bonding pads 51 of the lower integrated circuit 34.

The plural of spacer elements 38 are arranged on the lower integrated circuit 34. In the embodiment, the spacer elements 38 are form of metallic balls.

The upper integrated 40 are located on the lower integrated circuit 34 and adhered to the plural of space elements 38, a plurality of bonding pads 53 are formed on the upper integrated circuit 40.

The plural of second wires 42 are electrically connected the third electrodes 56 of the frame layer 32 to the bonding pads 53 of the upper integrated circuit 40.

The compound resin 44 is encapsulated the upper integrated circuit 40 and the lower integrated circuit 34.

Wherein the plural of first wires 36 are bonded from corresponding to the second electrodes 54 of the frame layer 32 to corresponding to the bonding pads 51 of the lower integrated circuit 34. The plural of first wires 36 are bonded from corresponding to the second electrodes 54 of the frame layer 32 to corresponding to the bonding pads 51 of the lower integrated circuit 34.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A stacked structure of integrated circuits, comprising:
a substrate having a first surface and a second surface opposite to the first surface, the second surface being formed with a plurality of first electrodes;
a frame layer having an upper surface on which a plurality of second electrodes and third electrodes are formed and a lower surface opposite to the upper surface, the lower surface of the frame layer being adhered to the first surface of the substrate so as to define a cavity by the substrate and the frame layer;
a lower integrated circuit being adhered onto the first surface of the substrate and within the cavity, a plurality of bonding pads being formed on the lower integrated circuit;
a plurality of first wires being electrically connected the second electrodes of the frame layer to the bonding pads of the lower integrated circuit;
a plurality of spacer elements arranged on the lower integrated circuit;
an upper integrated located on the lower integrated circuit and adhered to the plurality of space elements, a plurality of bonding pads being formed on the upper integrated circuit;
a plurality of second wires being electrically connected the third electrodes of the frame layer to the bonding pads of the upper integrated circuit;
a compound resin encapsulated the upper integrated circuit and the lower integrated circuit.

2. The stacked structure of integrated circuits according to claim 1, wherein the plurality of space elements are form of metallic balls.

3. A method for manufacturing a stacked structure of integrated circuit, comprises:
Providing a substrate having a first surface and a second surface opposite to the first surface, the second surface being formed with a plurality of first electrodes;
Providing a frame layer having an upper surface on which a plurality of second electrodes and third electrodes are formed and a lower surface opposite to the upper surface, the lower surface of the frame layer being adhered to the first surface of the substrate so as to define a cavity by the substrate and the frame layer;
Providing a lower integrated circuit being adhered onto the first surface of the substrate and within the cavity, a plurality of bonding pads being formed on the lower integrated circuit;
Providing a plurality of first wires being electrically connected the second electrodes of the frame layer to the bonding pads of the lower integrated circuit;
Providing a plurality of spacer elements arranged on the lower integrated circuit;
Providing an upper integrated located on the lower integrated circuit and adhered to the plurality of space elements;
Providing a plurality of second wires being electrically connected the third electrodes of the frame layer to the bonding pads of the upper integrated circuit; and
Providing a compound resin encapsulated the upper integrated circuit and the lower integrated circuit.

4. The method for manufacturing a stacked structure of integrated circuits according to claim 3, wherein the plurality of space elements are metallic balls.

5. The method for manufacturing a stacked structure of integrated circuits according to claim 3, wherein the first wires are bonded from the second electrodes of the frame layer to bonding pads of the lower integrated circuit.

6. The method for manufacturing a stacked structure of integrated circuits according to claim 3, wherein the second wires are bonded from the third electrodes of the frame layer to bonding pads of the upper integrated circuit.
